(19) United States
(12) Patent Application Publication
(10) Pub. No.: US 2008/0164926 A1
(43) Pub. Date: Jul. 10, 2008

(54) DUTY CYCLE CORRECTION CIRCUIT EMPLOYING SAMPLE AND HOLD CHARGE PUMPING METHOD

(75) Inventor: Young-don CHOI, Anseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/869,864

(22) Filed: Oct. 10, 2007

(30) Foreign Application Priority Data
Jan. 5, 2007 (KR) 10-2007-0001690

(51) Int. Cl. H03K 3/017; H03K 5/04

(52) U.S. Cl. 327/175

(57) ABSTRACT

A duty cycle correction circuit employing a sample and hold charge pumping method is disclosed. The duty cycle correction circuit includes a duty regulator which generates an output signal by regulating duty of an input signal in response to a regulation voltage, and a charge pump which generates the regulation voltage by inputting the output signal, wherein ripple of the regulation voltage is reduced by sampling the regulation voltage in a predetermined time interval.

### CROSS-REFERENCE TO RELATED PATENT APPLICATION

This application claims the benefit of Korean Patent Application No. 10-2007-0001690 filed on Jan. 05, 2007, the subject matter of which is hereby incorporated by reference.

### BACKGROUND OF THE INVENTION

1. Field of the Invention

The present invention finds application in the generation of voltage waveforms within a variety of integrated circuits. More particularly, the invention relates to a duty cycle correction circuit employing a sample and hold charge pumping method.

2. Description of the Related Art

Complementary Metal-Oxide Semiconductor (CMOS) integrated circuits generally include a number of interrelated circuits or elements related by the transmission and reception of common signals. In one perspective, these individual circuits and/or elements may be viewed as transmitting and receiving points connected by signal transmission paths (or “lines”). For example, the output of a CMOS inverter may be considered a transmitter (or transmission point), or the input of a simple CMOS amplifier, differential amplifier, or comparator may be considered a receiver (or reception point). A transmission line connecting any given transmitter and receiver may be characterized by its impedance termination or loading effect upon a signal being communicated. For signal waveforms having a variable amplitude, signal delay (or switching time response) is determined primarily by the ability of the transmitter (transmission point) to charge the capacitance component of the transmission line's impedance.

The impedance and conductance characteristics of transmission lines within a CMOS integrated circuit also determine noise levels. That is, potentially large noise voltages may occur on a transmission line due to capacitive coupling and high-level voltage switching on an adjacent transmission line.

In view of these noise effects, two types of interconnection which are relatively unaffected by such noise considerations are routinely employed in contemporary CMOS circuits. A first type is a single ended interconnection and a second type is a differential ended interconnection. A differential ended interconnection is mainly used to reduce common mode noise. In a single ended interconnection as well as a differential ended interconnection, a transmitted signal should be compensated to have 50% duty cycle in order to reduce the potential for timing distortion.

FIG. 1 is a diagram illustrating a conventional duty cycle correction circuit 100. Referring to FIG. 1, the duty cycle correction circuit 100 includes a duty regulator 110 and a charge pump 120. The duty regulator 110 outputs an output signal OUT by regulating duty of an input signal IN in response to a regulation voltage Vc. The charge pump 120 generates the regulation voltage Vc by inputting the output signal OUT.

FIG. 2 is a circuit diagram of the duty regulator 110 illustrated in FIG. 1. Referring to FIG. 2, the duty regulator 110 includes PMOS transistors 202 and 204 and NMOS transistors 206 and 208 connected in series between a power supply voltage VDD and a ground VSS. Gates of the first PMOS transistor 202 and the second NMOS transistor 208 are connected to the regulation voltage Vc, and gates of the second PMOS transistor 204 and the first NMOS transistor 206 are connected to the input signal IN. Also, drains of the second PMOS transistor 204 and the first NMOS transistor 206 are connected to the output signal OUT. The duty regulator 110 changes duty cycle of the output signal OUT based on the regulation voltage Vc.

FIG. 3 is a circuit diagram of the charge pump 120 illustrated in FIG. 1. Referring to FIG. 3, the charge pump 120 includes a first power source 302, a PMOS transistor 304, an NMOS transistor 306, and a second power source 308, which are connected in series between the power supply voltage VDD and ground voltage VSS. The charge pump 120 also includes a capacitor 310 connected between the regulation voltage Vc and ground VSS. Gates of the PMOS transistor 304 and the NMOS transistor 306 are connected to the output signal OUT, and drains thereof are connected to the regulation voltage Vc. In the charge pump 120, a current of the first power source 302 is charged in the capacitor 310 during a logic low period of the output signal OUT, and the charge of the capacitor 310 is discharged through the second power source 308 during a logic high period of the output signal OUT.

FIG. 4 is an exemplary timing diagram of the output signal OUT and the regulation voltage Vc according to operations of the charge pump 120 illustrated in FIG. 3. Referring to FIG. 4, the level of the regulation voltage Vc decreases during each logically high period of the output signal OUT (i.e., each “high”) and increases during each logically low period of the output signal OUT (i.e., each “low”). When the duty cycle of the output signal OUT is above 50%, the regulation voltage Vc exhibits a decreased ripple voltage, but when the duty cycle of the output signal OUT is below 50%, the regulation voltage Vc exhibits an increased ripple voltage. When the duty cycle of the output signal OUT regulated by the regulation voltage Vc is exactly 50%, the regulation voltage Vc exhibits a stable, uniform ripple voltage.

However, when the ripple voltage level of the regulation voltage Vc is large, jitter increases on the regulation voltage Vc. In order to reduce the jitter of the regulation voltage Vc, the capacitance of capacitor 310 should be increased. However, when the capacitance of capacitor 310 increases, the response time required to regulate the duty cycle of the output signal OUT at 50% becomes quite long.

### SUMMARY OF THE INVENTION

Embodiments of the invention provide a duty cycle correction circuit capable of reducing the ripple of a regulation voltage by employing a sample and hold charge pumping method.

In one embodiment, the invention provides a duty cycle correction circuit comprising; a duty regulator generating an output signal by regulating the duty of an input signal in response to a regulation voltage, and a charge pump generating the regulation voltage by inputting the output signal, wherein ripple of the regulation voltage is reduced by sampling the regulation voltage at a predetermined time interval.

In a related aspect, the duty regulator may comprise; a first PMOS transistor having a source connected to a power supply voltage and a gate connected to the regulation voltage, a second PMOS transistor having a source connected to the drain of the first PMOS transistor and a source connected to the input signal, a first NMOS transistor having a drain connected to the drain of the second PMOS transistor and a gate connected to the input signal, and a second NMOS transistor having a drain connected to the source of the first NMOS transistor, a gate connected to the regulation voltage, and a source connected to ground.

In another related aspect, the charge pump may comprise; a first power source having a first end connected to a power supply voltage, a PMOS transistor having a source connected to a second end of the first power source, a gate connected to the output signal, and a drain connected to a first voltage node, an NMOS transistor having a drain connected to the first voltage node, and a gate connected to the output signal, a second power source having a first end connected to the source of the NMOS transistor and a second end connected to ground, a first capacitor connected between the first voltage node and ground, a first switch connected between the first voltage node and a second voltage node, the first switch being controlled by a first control signal, a second capacitor connected between the second voltage node and ground, a second switch connected between the second voltage node and the regulation voltage, the second switch being controlled by a second control signal, and a third capacitor connected between the regulation voltage and ground.

In another related aspect, the charge pump may alternately comprise; a first power source having a first end connected to a power supply voltage, a PMOS transistor having a source connected to a second end of the first power source, a gate connected to the output signal, and a drain connected to a first voltage node, an NMOS transistor having a drain connected to the first voltage node, and a gate connected to the output signal, a second power source having a first end connected to the source of the NMOS transistor and a second end connected to ground, a first capacitor connected between the first voltage node and ground, a first switch connected between the first voltage node and a second voltage node and controlled by the logical inverse of a first control signal, a second capacitor connected between the second voltage node and ground, a second switch connected between the second voltage node and the regulation voltage and controlled by a second control signal, a third switch connected between the first voltage node and a third voltage node and controlled by the first control signal, a third capacitor connected between the third voltage node and ground, a fourth switch connected between the third voltage node and the regulation voltage and controlled the logical inverse of the second control signal, and a fourth capacitor connected between the regulation voltage and ground.

### BRIEF DESCRIPTION OF THE DRAWINGS

FIG. 1 is a diagram illustrating a conventional duty cycle correction circuit;

FIG. 2 is a circuit diagram of a duty regulator illustrated in FIG. 1;

FIG. 3 is a circuit diagram of a charge pump illustrated in FIG. 1;

FIG. 4 is a waveform diagram of an output signal and a regulation voltage according to operations of the charge pump illustrated in FIG. 3;

FIG. 5 is a waveform diagram illustrating the effect of a sample and hold charge pumping method on reducing the ripple of a regulation voltage;

FIG. 6 is a circuit diagram of a charge pump according to an embodiment of the present invention;

FIG. 7 is a diagram for describing a control signal generation circuit according to an embodiment of the present invention;

FIG. 8 is a graph illustrating a simulation result of the first voltage node VC0, the second voltage node VC1, and the regulation voltage Vc of the charge pump 120a illustrated in FIG. 6;

FIG. 9 is a circuit diagram of a charge pump according to another embodiment of the present invention;

FIG. 10 is a diagram for describing a control signal generation circuit according to another embodiment of the present invention;

FIG. 11 is a graph illustrating simulation result of the first voltage node VC0, the second voltage node VC1, the third node voltage VC2, and the regulation voltage Vc of the charge pump 120b; and

FIGS. 12 and 13 are diagrams illustrating simulation results of comparing locking time and ripple of a regulation voltage according to a duty error of an input signal of a duty cycle correction circuit.

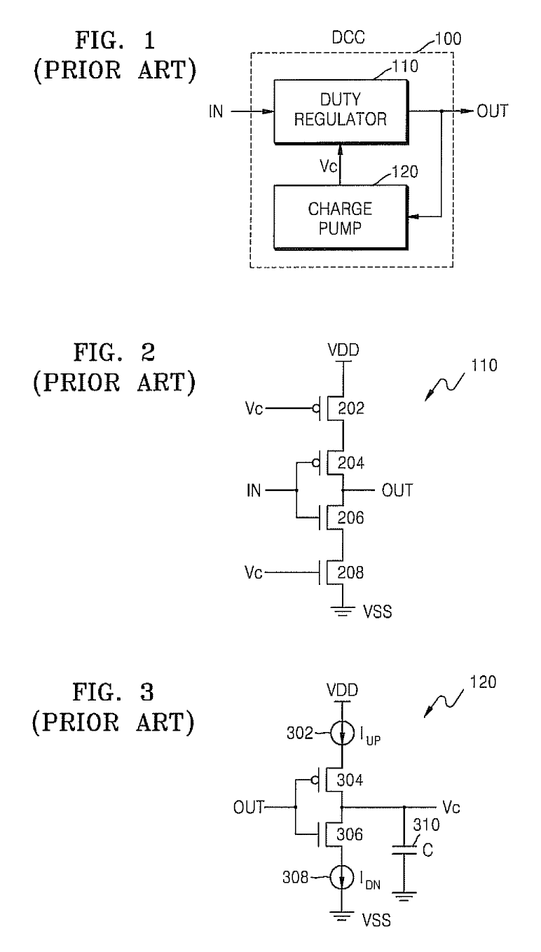

### DESCRIPTION OF EMBODIMENTS

Several embodiments of the invention will now be described with reference to the accompanying drawings. Throughout the drawings and written description, like reference numerals and labels indicate like or similar elements.

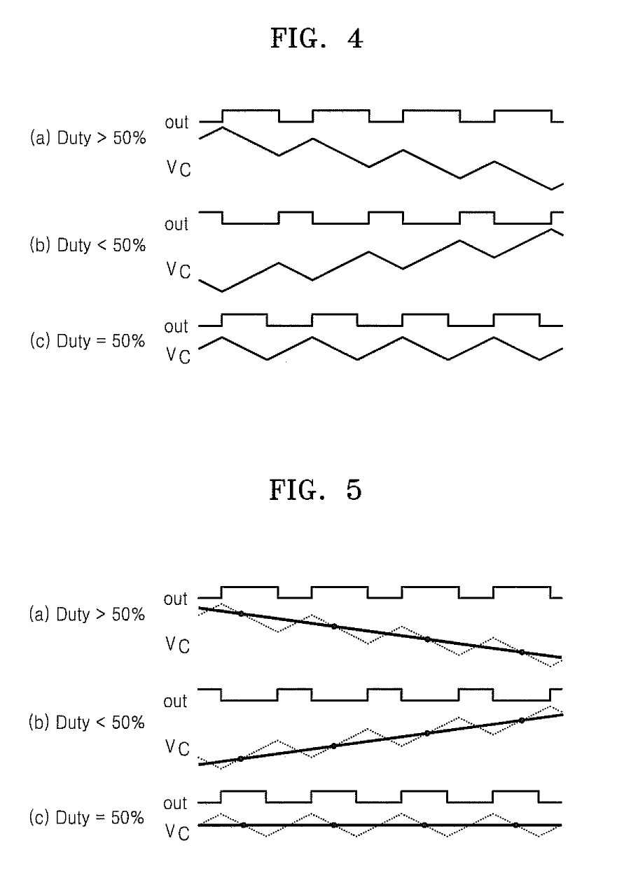

FIG. 5 is a waveform diagram illustrating the effect of a sample and hold charge pumping method on reducing the ripple of a regulation voltage. Referring to FIG. 5, the ripple on a regulation voltage Vc is reduced by sampling the regulation voltage Vc at predetermined time intervals identified by the timing diagram of the output signal OUT and the regulation voltage Vc shown in FIG. 4.

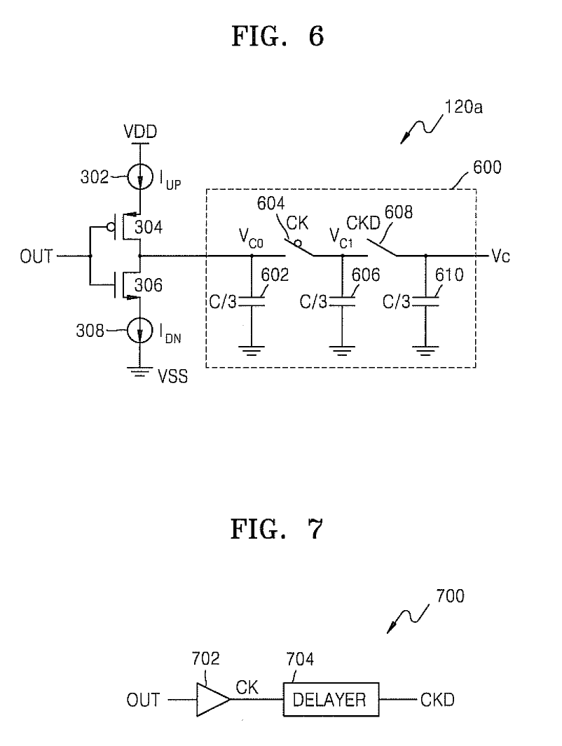

FIG. 6 is a circuit diagram for a charge pump 120a according to an embodiment of the present invention. Referring to FIG. 6, the charge pump 120a, similar to the charge pump 120 of FIG. 3, includes a first power source 302, a PMOS transistor 304, an NMOS transistor 306, and a second power source 308 which are connected in series between a power supply voltage VDD, and a ground VSS. Drains of the PMOS transistor 304 and the NMOS transistor 306 become a first voltage node VC0. Additionally, the charge pump 120a further includes a sample and hold circuit 600 which is connected to the first voltage node VC0.

The sample and hold circuit 600 includes a first capacitor 602 which is connected between the first voltage node VC0 and ground VSS, a first switch 604 which is connected between the first voltage node VC0 and a second voltage node VC1, a second capacitor 606 which is connected between the second voltage node VC1 and ground VSS, a second switch 608 which is connected between the second voltage node VC1 and the regulation voltage Vc, and a third capacitor 610 which is connected between the regulation voltage Vc and ground VSS. The first switch 604 is turned on/off in response to a first control signal CK, and the second switch 608 is turned on/off in response to a second control signal CKD. The first through third capacitors 602, 606, and 610 have the same capacitance C/3, wherein the total capacitance of the first through third capacitors 602, 606, and 610 is equal to capacitance C of the capacitor 310 illustrated in FIG. 3. The first through third capacitors 602, 606, and 610 are sequentially charged in response to the first control signal CK and the second control signal CKD.

FIG. 7 is a circuit diagram illustrating a control signal generation circuit 700 capable of generating first and second control signals CK and CKD according to an embodiment of the present invention. Referring to FIG. 7, the control signal generation circuit 700 includes a buffer 702 which outputs the first control signal CK by inputting an output signal OUT, and a delayer 704 which generates the second control signal CKD by inputting the first control signal CK. The first and second control signals CK and CKD respectively is a signal in which predetermined time is delayed from the output signal OUT.

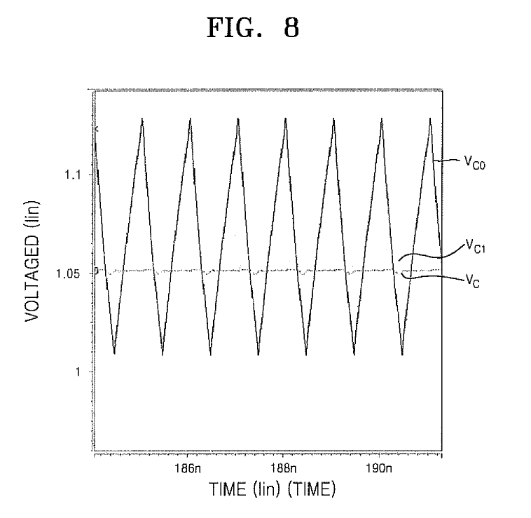

FIG. 8 is a graph illustrating a simulation result for the first voltage node VC0, the second voltage node VC1, and the regulation voltage Vc of the charge pump 120a illustrated in FIG. 6. Referring to FIG. 8, ripple of the second voltage node VC1 is remarkably reduced compared to ripple of the first voltage node VC0, and ripple of the regulation voltage Vc can be hardly seen.

The charge pump 120a substitutes the charge pump 120 of the duty cycle correction circuit 100 of FIG. 1. Accordingly, the duty cycle correction circuit 100 regulates 50% duty cycle of the output signal OUT to the regulation voltage Vc that barely has ripple.

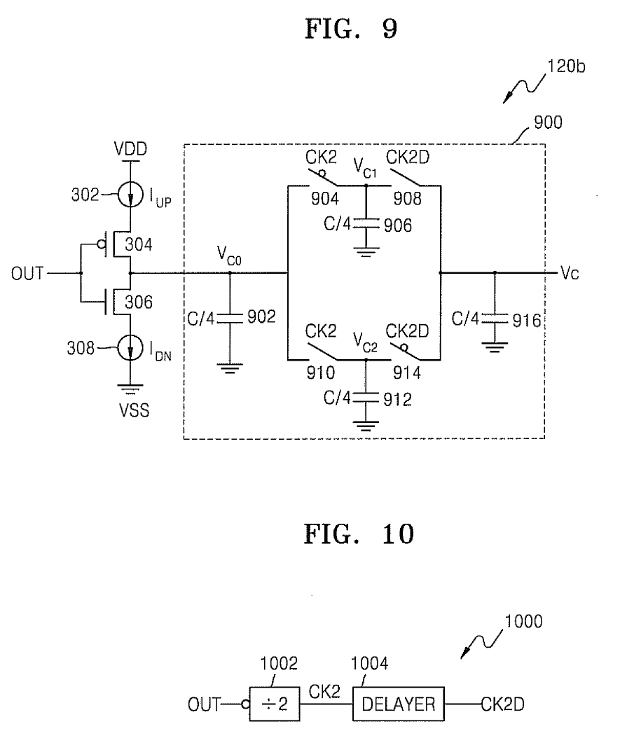

FIG. 9 is a circuit diagram of a charge pump 120b according to another embodiment of the present invention. Referring to FIG. 9, the charge pump 120b includes a sample and hold circuit 900, which operates in response to control signals CK2 and CK2D which are divided by two, instead of the sample and hold circuit 600 of FIG. 6.

The sample and hold circuit 900 includes a first capacitor 902 which is connected between a first voltage node VC0 and a ground VSS, a first switch 904 which is connected between the first voltage node VC0 and a second voltage node VC1, a second capacitor 906 which is connected between the second voltage node VC1 and ground VSS, a second switch 908 which is connected between the second voltage node VC1 and a regulation voltage Vc, a third switch 910 which is connected between the first voltage node VC0 and a third voltage node VC2, a third capacitor 912 which is connected between the third voltage node VC2, and ground VSS, a fourth switch 914 which is connected between the third voltage node VC2 and the regulation voltage Vc, and a fourth capacitor 916 which is connected between the regulation voltage Vc and ground VSS.

The first switch 904 is turned on/off in response to the logical inverse of the third control signal CK2, the second switch 908 is turned on/off in response to the fourth control signal CK2D, the third switch 910 is turned on/off in response to the third control signal CK2, and the fourth switch 914 is turned on/off in response to the logical inverse of the fourth control signal CK2D. The first through fourth capacitors 902, 906, 912, and 916 have the same capacitance C/4, wherein the total capacitance of the first through fourth capacitors 902, 906, 912, and 916 is equal to capacitance C of the capacitor 310 of FIG. 3. The first and second capacitors 902 and 906 and the third and fourth capacitors 912 and 916 are alternatively charged in response to the third and fourth control signals CK2 and CK2D.

FIG. 10 is a circuit diagram illustrating a control signal generation circuit 1000 generating third and fourth control signals CK2 and CK2D according to another embodiment of the present invention. Referring to FIG. 10, the control signal generation circuit 1000 includes a divider 1002 which generates the third control signal CK2 by dividing the output signal OUT into two, and a delayer 1004 which generates the fourth control signal CK2D by inputting the third control signal CK2.

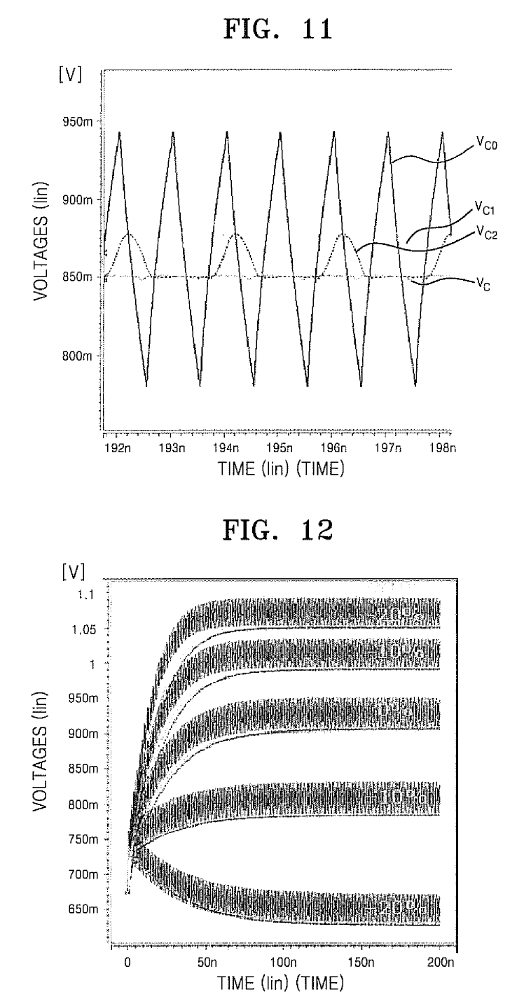

FIG. 11 is a graph illustrating simulation result of the first voltage node VC0, the second voltage node VC1, the third voltage node VC2, and the regulation voltage Vc of the charge pump 120b. Referring to FIG. 8, ripples of the second and third voltage nodes VC1 and VC2 are remarkably reduced compared to ripple of the first voltage node VC0, and ripple of the regulation voltage Vc can be hardly seen.

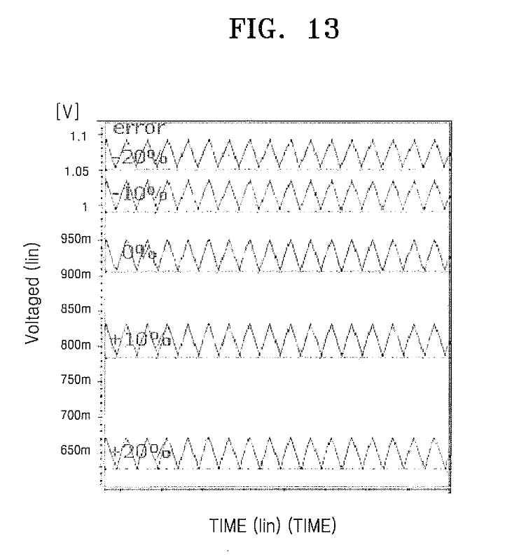

FIGS. 12 and 13 are voltage waveform diagrams illustrating simulation results that compare locking time and ripple for the regulation voltage Vc according to a duty error of the input signal IN of the duty cycle correction circuit 100. Referring to FIG. 12, locking times according to duty errors (−20%, −10%, 0%, 10%, 20%) of the input signal IN of the charge pump 120 of FIG. 3, the charge pump 120a of FIG. 6, and the charge pump 120b of FIG. 9 are similar. As illustrated in FIG. 13, ripples of the regulation voltage Vc of the charge pump 120a of FIG. 6 and the charge pump 120b of FIG. 9 are remarkably reduced compared to ripple of the regulation voltage of the charge pump 120 of FIG. 3 during a duty locking.

While the present invention has been particularly shown and described with reference to exemplary embodiments thereof, it will be understood by those of ordinary skill in the art that various changes in form and details may be made therein without departing from the scope of the present invention as defined by the following claims.

What is claimed is:

1. A duty cycle correction circuit comprising:
a duty regulator generating an output signal by regulating the duty of an input signal in response to a regulation voltage; and
a charge pump generating the regulation voltage by inputting the output signal, wherein ripple of the regulation voltage is reduced by sampling the regulation voltage at a predetermined time interval.

2. The duty cycle correction circuit of claim 1, wherein the duty regulator comprises:
a first PMOS transistor having a source connected to a power supply voltage and a gate connected to the regulation voltage;
a second PMOS transistor having a source connected to the drain of the first PMOS transistor and a source connected to the input signal;
a first NMOS transistor having a drain connected to the drain of the second PMOS transistor and a gate connected to the input signal; and
a second NMOS transistor having a drain connected to the source of the first NMOS transistor, a gate connected to the regulation voltage, and a source connected to ground.

3. The duty cycle correction circuit of claim 1, wherein the charge pump comprises:
a first power source having a first end connected to a power supply voltage;
a PMOS transistor having a source connected to a second end of the first power source, a gate connected to the output signal, and a drain connected to a first voltage node;
an NMOS transistor having a drain connected to the first voltage node, and a gate connected to the output signal;
a second power source having a first end connected to the source of the NMOS transistor and a second end connected to ground;
a first capacitor connected between the first voltage node and ground;
a first switch connected between the first voltage node and a second voltage node, the first switch being controlled by a first control signal;
a second capacitor connected between the second voltage node and ground;
a second switch connected between the second voltage node and the regulation voltage, the second switch being controlled by a second control signal; and
a third capacitor connected between the regulation voltage and ground.

4. The duty cycle correction circuit of claim 3, further comprising:
a control signal generator generating the first and second control signals, wherein the control signal generator comprises:
a buffer outputting the first control signal by inputting the output signal; and
a delayer generating the second control signal by inputting the first control signal.

5. The duty cycle correction circuit of claim 3, wherein the first through third capacitors of the charge pump have the same capacitance.

6. The duty cycle correction circuit of claim 1, wherein the charge pump comprises:
a first power source having a first end connected to a power supply voltage;
a PMOS transistor having a source connected to a second end of the first power source, a gate connected to the output signal, and a drain connected to a first voltage node;
an NMOS transistor having a drain connected to the first voltage node, and a gate connected to the output signal;
a second power source having a first end connected to the source of the NMOS transistor and a second end connected to ground;
a first capacitor connected between the first voltage node and ground;
a first switch connected between the first voltage node and a second voltage node and controlled by the logical inverse of a first control signal;
a second capacitor connected between the second voltage node and ground;
a second switch connected between the second voltage node and the regulation voltage and controlled by a second control signal;
a third switch connected between the first voltage node and a third voltage node and controlled by the first control signal;
a third capacitor connected between the third voltage node and ground;
a fourth switch connected between the third voltage node and the regulation voltage and controlled the logical inverse of the second control signal; and
a fourth capacitor connected between the regulation voltage and ground.

7. The duty cycle correction circuit of claim 6, further comprising:
a control signal generator generating the first and second control signals, wherein the control signal generator comprises:
a divider generating the first control signal by dividing the output signal by two; and
a delayer generating the second control signal by inputting the first control signal.

8. The duty cycle correction circuit of claim 6, wherein the first through fourth capacitors of the charge pump have the same capacitance.
